(19) United States
(12) Patent Application Publication
(10) Pub. No.: US 2021/0003678 A1
(43) Pub. Date: Jan. 7, 2021

(54) ELECTRONIC DEVICE, LIGHT RECEIVING DEVICE, LIGHT PROJECTING DEVICE, AND DISTANCE MEASUREMENT METHOD

(71) Applicant: KABUSHIKI KAISHA TOSHIBA, Minato-ku (JP)

(72) Inventors: Hidenori OKUNI, Yokohama (JP); Tuan Thanh TA, Kawasaki (JP); Satoshi KONDO, Kawasaki (JP); Toshiki SUGIMOTO, Yokohama (JP); Kentaro YOSHIOKA, Kawasaki (JP); Akihide SAI, Yokohama (JP)

(73) Assignee: KABUSHIKI KAISHA TOSHIBA, Minato-ku (JP)

(21) Appl. No.: 16/811,120

(22) Filed: Mar. 6, 2020

(30) Foreign Application Priority Data
Jul. 3, 2019 (JP) 2019-124697

(51) Int. Cl. G01S 7/4863; G01S 7/4865; G01S 17/10

(52) U.S. Cl. CPC G01S 7/4863; G01S 17/10; G01S 7/4865

(57) ABSTRACT

An electronic apparatus has a light detector configured to detect light by converting a reception photon into a signal and incapable of converting an additional photon into the signal during a recovery period after a reception of photons, a light projector configured to project light having a pulse width different from any of n times the recovery period (n is an integer of 1 or more), and a processor configured to measure a distance to a target object by using a time difference between a timing at which light is projected by the light projector and a timing at which light comprising a reflected wave is detected by the light detector, wherein the reflected wave is obtained by reflection of the light projected by the light projector onto the target object.

### CROSS REFERENCE TO RELATED APPLICATIONS

This application is based upon and claims the benefit of priority from the prior Japanese Patent Application No. 2019-124697, filed on Jul. 3, 2019, the entire contents of which are incorporated herein by reference.

### FIELD

Embodiments described herein relate generally to an electronic device, a light receiving device, a light projecting device, and a distance measurement method.

### BACKGROUND

Examples of photodetector elements that convert received light into an electrical signal include an avalanche photodiode (hereinafter referred to as APD). In a case where an APD operates in the Geiger mode in which a reverse bias voltage higher than the breakdown voltage is applied to the APD, the APD has capability of detecting the weak light of one photon. However, although the APD operating in the Geiger mode has higher sensitivity, its operating state changes after detecting a photon, making it difficult to detect the subsequent light with high sensitivity. For this reason, the APD needs to undergo recovery operation after photon detection. The recovery operation includes operation of raising the cathode voltage of the APD. However, the APD is incapable of receiving any photons during a recovery period until the cathode voltage returns to a desired voltage. This recovery period is also referred to as dead time.

A distance measurement device using an APD as a light receiving unit measures a distance to a target object by using a time difference between a timing at which a laser beam is projected from a light projecting unit and a timing at which the laser beam is received by a light receiving unit after being reflected by a target object.

Unfortunately, however, the APD is incapable of receiving light during its recovery period, leading to reduction in distance measurement accuracy.

### BRIEF DESCRIPTION OF THE DRAWINGS

FIG. 1 is a block diagram illustrating a schematic configuration of an electronic device 1 according to an embodiment;

FIG. 2 is a view illustrating an example of a light receiving sensor having SiPMs for a plurality of pixels arranged in the vertical and horizontal directions;

FIG. 3A is a diagram illustrating light projection timing at which the light projecting unit projects a laser beam;

FIG. 3B is a diagram illustrating a reception timing of reflected light received by a light receiving unit;

FIG. 4A is a diagram illustrating light reception time data when it is assumed that the APD has no dead time; FIG. 4B is a diagram illustrating a light reception time distribution when it is assumed that the APD has no dead time;

FIG. 5A is a diagram illustrating light reception time data when the APD has a dead time;

FIG. 5B is a diagram illustrating a light reception time distribution when the APD has a dead time;

FIG. 6 is a diagram illustrating a relationship between a pulse width of the laser beam projected by the light projecting unit and a distance measurement error; FIG. 7A is a diagram illustrating light reception time data when the pulse width of the laser beam is set to 2.3 times the dead time;

FIG. 7B is a diagram illustrating light reception time distribution when the pulse width of the laser beam is set to 2.3 times the dead time;

FIG. 8 is a flowchart illustrating processing operation of an electronic device according to the present embodiment; and

FIG. 9 is a schematic perspective view illustrating an example in which the light receiving unit and a signal processing unit are mounted on a semiconductor substrate.

### DETAILED DESCRIPTION

An electronic apparatus has a light detector configured to detect light by converting a reception photon into a signal and incapable of converting an additional photon into the signal during a recovery period after a reception of photons, a light projector configured to project light having a pulse width different from any of n times the recovery period (n is an integer of 1 or more), and a processor configured to measure a distance to a target object by using a time difference between a timing at which light is projected by the light projector and a timing at which light comprising a reflected wave is detected by the light detector, wherein the reflected wave is obtained by reflection of the light projected by the light projector onto the target object.

Hereinafter, embodiments of an electronic device, a light receiving device, a light projecting device, and a distance measurement method will be described with reference to the drawings. The following description will focus on main components of the electronic device, the light receiving device, and the light projecting device. However, the electronic device, the light receiving device, and the light projecting device may have components and functions that are not illustrated or described.

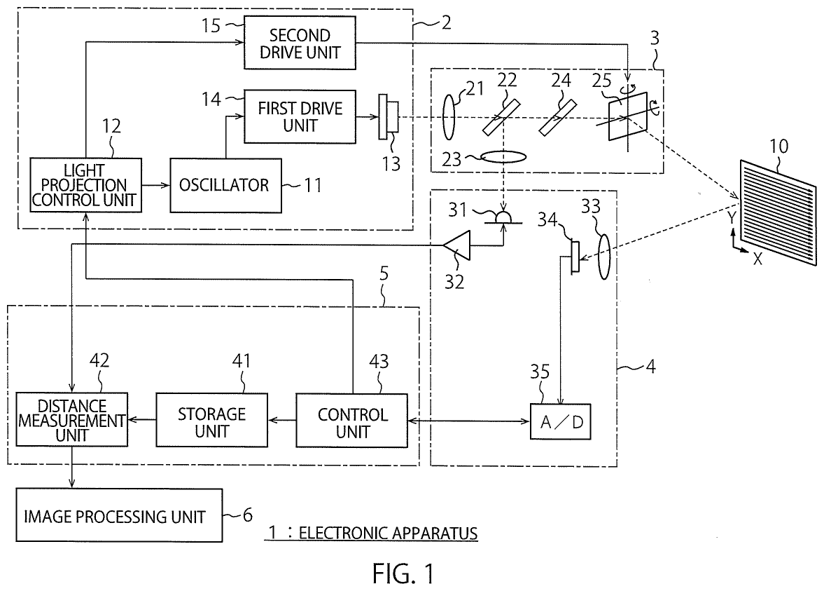

FIG. 1 is a block diagram illustrating a schematic configuration of an electronic device 1 according to an embodiment. The electronic device 1 in FIG. 1 performs distance measurement using a ToF method. The electronic device 1 in FIG. 1 includes a light projecting unit (light projector) 2, a light control unit 3, a light receiving unit (light detector) 4, a signal processing unit 5, and an image processing unit 6. At least a part of the electronic device 1 in FIG. 1 can be implemented by one or more semiconductor integrated circuits (ICs). For example, the signal processing unit 5 and the image processing unit 6 may be integrated in one semiconductor chip, or these units may be integrated together with the light receiving unit 4 in this semiconductor chip. Furthermore, integration on this semiconductor chip may also include the light projecting unit 2.

The light projecting unit 2 projects light. The light projected by the light projecting unit 2 is a laser beam in a predetermined frequency band, for example. The laser beam is coherent light having the same phase and frequency. The light projecting unit 2 projects a pulsed laser beam intermittently at a predetermined period. The period in which the light projecting unit 2 projects the laser beam is a time interval being the time required for the signal processing unit 5 to measure the distance on the basis of one pulse of the laser beam, or longer. As will be described below, the light projecting unit 2 projects light having a pulse width different from any of n times the recovery period (n is an integer of 1 or more) of the light receiving unit 4.

The light projecting unit 2 includes an oscillator 11, a light projection control unit 12, a light source 13, a first drive unit 14, and a second drive unit 15. The oscillator 11 generates an oscillation signal corresponding to the period of projecting the laser beam. The first drive unit 14 intermittently supplies power to the light source 13 in synchronization with the oscillation signal. The light source 13 intermittently emits a laser beam on the basis of the power from the first drive unit 14. The light source 13 may be a laser element that emits a single laser beam or a laser unit that emits a plurality of laser beams simultaneously. The light source 13 emits a pulsed laser beam with any pulse shape. For example, the pulse shape may be rectangular, triangular, a trigonometric function shape, or a Gaussian curve shape. The light projection control unit 12 controls the second drive unit 15 in synchronization with the oscillation signal. The second drive unit 15 supplies a drive signal synchronized with the oscillation signal to the light control unit 3 in response to an instruction from the light projection control unit 12.

The light control unit 3 controls the traveling direction of the laser beam emitted from the light source 13. The light control unit 3 controls the traveling direction of the received laser beam.

The light control unit 3 includes a first lens 21, a beam splitter 22, a second lens 23, a half mirror 24, and a scanning mirror 25.

The first lens 21 condenses the laser beam emitted from the light projecting unit 2 and guides the beam to the beam splitter 22. The beam splitter 22 branches the laser beam from the first lens 21 in two directions and guides the branched beams to the second lens 23 and the half mirror 24. The second lens 23 guides the branched light from the beam splitter 22 to the light receiving unit 4. The reason for guiding the laser beam to the light receiving unit 4 is to detect a light projection timing in the light receiving unit 4.

The half mirror 24 transmits the branched light from the beam splitter 22 and guides the light to the scanning mirror 25. The half mirror 24 reflects the laser beam including reflected light incident on the electronic device 1 in the direction of the light receiving unit 4.

The scanning mirror 25 performs rotational drive of the mirror surface in synchronization with the drive signal from the second drive unit 15 in the light projecting unit 2. This configuration works to control the reflection direction of the branched light (laser beam) transmitted through the half mirror 24 to be incident on the mirror surface of the scanning mirror 25. With the rotational driving of the mirror surface of the half mirror 24 at a constant period, the laser beam emitted from the light control unit 3 can be scanned in at least a one-dimensional direction. With axes for rotational driving of the mirror surface provided in two directions, the laser beam emitted from the light control unit 3 can also be scanned in the two-dimensional direction. FIG. 1 illustrates an example in which the scanning mirror 25 scans the laser beam projected from the electronic device 1 in the X direction and the Y direction. The scanning mirror 25 may also change the optical characteristics to switch the traveling direction of the laser beam in addition to physically rotating the mirror surface.

In a case where a target object 10 such as a person or an object exists within a scanning range of the laser beam projected from the electronic device 1, the laser beam is reflected by the target object 10. The reflected light, that is, the light reflected by the target object 10 is received by the light receiving unit 4.

The light receiving unit 4 detects light by converting a reception photon into a signal and incapable of converting an additional photon into the signal during a recovery period after a reception of photons. In this way, the light receiving unit 4 is incapable of receiving new light within the recovery period after receiving a predetermined number of photons. The length of the recovery period is set so that the pulse width of the laser beam projected by the light projecting unit 2 satisfies a relationship that the pulse width is different from any of n times the recovery period (n is an integer of 1 or more). The light receiving unit 4 includes a photodetector 31, an amplifier 32, a third lens 33, a light receiving sensor 34, and an A/D converter 35. The photodetector 31 receives the light branched by the beam splitter 22 and converts the light into an electrical signal. The photodetector 31 can detect the projection timing of the laser beam. The amplifier 32 amplifies the electrical signal output from the photodetector 31. As will be described below, the light receiving unit 4 determines the light reception timing of the reflected wave on the basis of light reception signals received before and after the recovery period.

The third lens 33 forms an image of the laser beam reflected by the target object 10 onto the light receiving sensor 34. The light receiving sensor 34 receives the laser beam and converts it into an electrical signal. The light receiving sensor 34 includes the above-described Silicon Photomultiplier (SiPM). The light receiving sensor 34 will be described in detail below.

The A/D converter 35 samples the electrical signal output from the light receiving sensor 34 at a predetermined sampling rate, performs A/D conversion on the signal, and generates a digital signal.

The signal processing unit 5 measures the distance to the target object 10 that has reflected the laser beam, and stores a digital signal corresponding to the laser beam in a storage unit 41. The signal processing unit 5 includes a storage unit 41, a distance measurement unit 42, and a control unit 43.

The distance measurement unit 42 measures the distance to the target object 10 on the basis of the laser beam and the reflected light. The processing operation of the distance measurement unit 42 is executed by a processor, processing circuitry etc. More specifically, the distance measurement unit 42 measures the distance to the target object on the basis of a time difference between the projection timing of the laser beam and the reception timing of the reflected light included in the laser beam received by the light receiving sensor 34. That is, the distance measurement unit 42 measures the distance on the basis of the following Formula (1).

Distance=speed of light×(light reception timing of reflected light−laser beam projection timing)/2. (1)

In this way, the distance measurement unit 42 measures a distance to a target object by using a time difference between a timing at which light is projected by the light projector and a timing at which light comprising a reflected wave is detected by the light detector. The reflected wave is obtained by reflection of the light projected by the light projector onto the target object.

The “reception timing of reflected light” in Formula (1) is more exactly the reception timing of reflected light at a peak position. The control unit 43 detects the peak position of the reflected light included in the laser beam on the basis of the digital signal generated by the A/D converter 35.

In addition to the control to store the A/D converted digital signal in the storage unit 41, the control unit 43 performs generation of light reception time data, generation of light reception time distribution, determination of reception timing of reflected light, or the like.

Although FIG. 1 illustrates an example in which the distance measurement unit 42 measures the distance to the target object on the basis of the digital signal corresponding to the received light data stored in the storage unit 41, the storage unit 41 is not an essential component. The distance measurement unit 42 may perform distance measurement using the digital signal corresponding to the light reception data converted by the A/D converter 35 without storing the signal in the storage unit 41. In this case, the control unit 43 and the distance measurement unit 42 may be integrated to each other.

The SiPM included in the light receiving sensor 34 has a plurality of avalanche photodiodes (hereinafter referred to as APDs) arranged in the two-dimensional direction. Among the plurality of APDs, the plurality of first APDs receives the laser beam incident from a first direction, while the plurality of second APDs receives light incident from a second direction different from the first direction.

When the APD operates in the Geiger mode in which a voltage higher than the breakdown voltage is applied between an anode and a cathode of the APD, the APD is capable of detecting the weak light of one photon. However, the cathode voltage of the APD falls after the APD detects a photon, making the APD incapable of detecting another photon. To handle this, the APD that has detected the photon needs to undergo recovery operation (also referred to as reset operation) for raising the cathode voltage. The period until the cathode voltage is raised to enable photon detection is referred to as a recovery period or dead time. The APD is incapable of detecting photons during the dead time period. Accordingly, reflected light arriving during that period is not to be detected by the light receiving unit 4, leading to an occurrence of an error in the distance measured by the distance measurement unit 42.

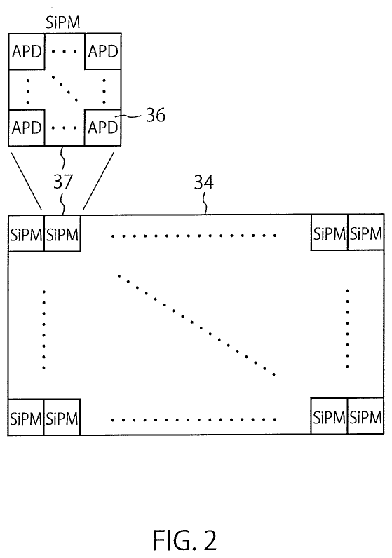

To manage this, the light receiving sensor 34 receives reflected light with one SiPM in which a plurality of APDs is 36 arranged in the vertical and horizontal directions, as one pixel. FIG. 2 illustrates an example of the light receiving sensor 34 in which a plurality of pixels of SiPM 37 is arranged in the vertical and horizontal directions with the SiPM 37 with a plurality of APMs 36 arranged in the vertical and horizontal directions, as one pixel. For example, with a configuration in which the SiPM 37 includes two by two APDs 36 in both vertical and horizontal directions, it is possible, with one SiPM 37, to receive four photons, enabling reception of photons with another APD 36 during the dead time of some APD 36s in the SiPM 37.

In this manner, the more the number of APDs 36 included in each of the SiPMs 37, the shorter the dead time during which the SiPM 37 is incapable of receiving light. On the other hand, increasing the number of APDs 36 in each of the SiPMs 37 would increase the mounting area of the light receiving sensor 34.

The light projecting unit 2 intermittently projects a laser beam having a predetermined pulse width. The laser beam projected from the light projecting unit 2 is reflected by a target object and received by the light receiving unit 4. With this configuration, the laser beam having a predetermined pulse width projected by the light projecting unit 2 is reflected by the target object and received by the light receiving unit 4 as reflected light having substantially the same pulse width.

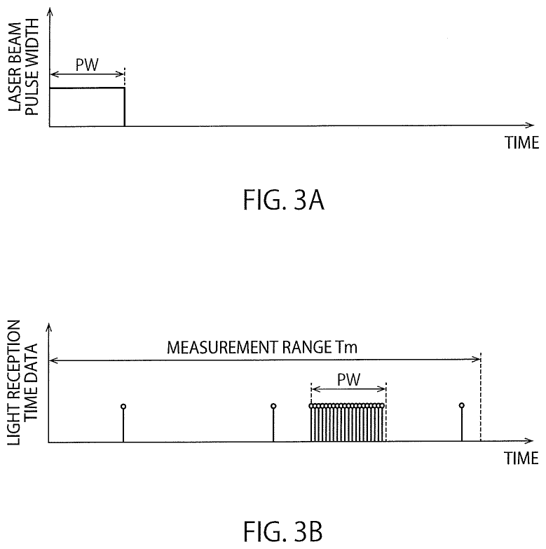

FIGS. 3A and 3B are diagrams illustrating the light projection timing at which the light projecting unit 2 projects a laser beam and illustrating the reception timing of the reflected light received by the light receiving unit 4, respectively. In FIGS. 3A and 3B, the pulse width at which the light projecting unit 2 projects the laser beam is PW, and the period (measurement range) in which the light receiving unit 4 receives the laser beam is Tm. The light receiving unit 4 receives ambient light irregularly, in addition to the reflected light. FIG. 3B schematically illustrates each of photons included in the reflected light and the ambient light using a vertical line. As illustrated in the figure, the ambient light is received at irregular timings before and after reception of the reflected light.

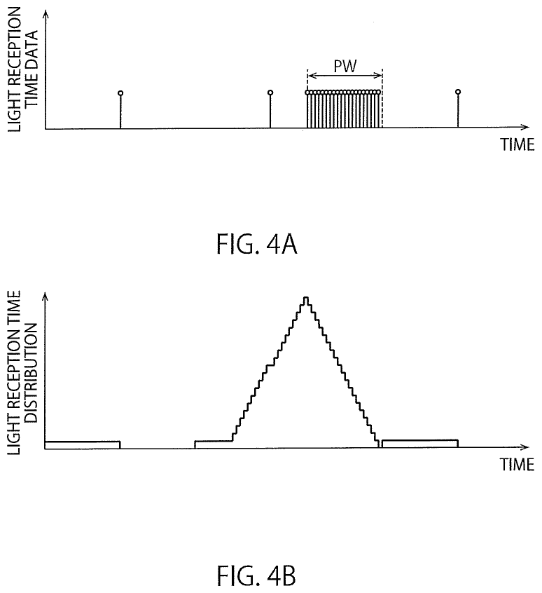

FIGS. 4A and 4B are diagrams illustrating light reception time data and light reception time distribution of the light receiving sensor 34 when it is assumed that the APD 36 has no dead time. The horizontal axis in FIGS. 4A and 4B represents the time. FIG. 4A illustrates photons received at each of time points. FIG. 4B illustrates the number of photons received within a period having the same length as the pulse width at which the light projecting unit 2 projects the laser beam.

As illustrated in FIG. 4B, the number of photons received within a period having the same length as the pulse width increases together with an increase in the length of the period during which reflected light is received within that period. Accordingly, the number of received photons increases linearly, and decreases linearly after reaching the maximum number.

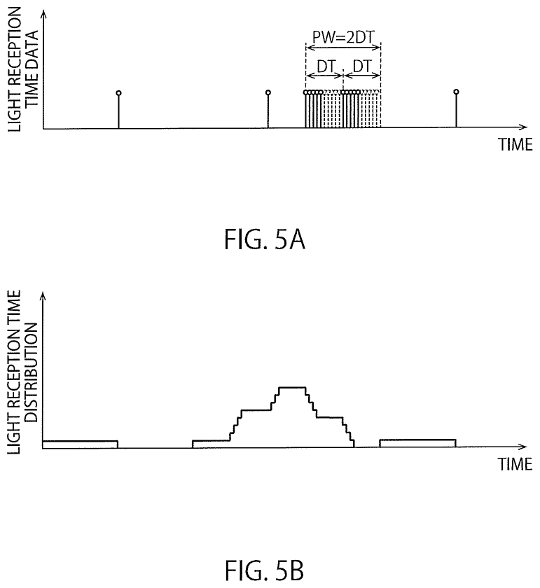

FIGS. 5A and 5B are diagrams illustrating light reception time data and light reception time distribution of the light receiving sensor 34 in a case where the APD 36 has a dead time. FIG. 5B illustrates an example in which the light receiving sensor 34 is implemented with a SiPM 37 including a plurality of APDs 36. For example, in a case where the SiPM 37 includes two by two APDs 36 in the vertical and horizontal directions, photons can be received until all four APDs 36 in the SiPM 37 have received photons. FIG. 5A illustrates an example in which dead time becomes necessary after the light receiving sensor 34 receives four photons. FIG. 5A is also an example in which the pulse width of the laser beam projected by the light projecting unit 2 has twice the length of the dead time of the APD 36. In this case, the light receiving sensor 34 can receive four photons in a period having the same length as the dead time. Therefore, the maximum number of photons received within the same length of period as the pulse width would be eight as illustrated in FIG. 5B. Compared to FIG. 5A where the APD 36 is assumed to have no dead time, the number of received photons is smaller.

The smaller number of photons received by the light receiving sensor 34 leads to difficulty in accurately grasping the light receiving timing of the reflected light. The distance measurement unit 42 measures the distance on the basis of the time difference between the light projection timing and the light reception timing. Therefore, in a case where only a part of the reflected light can be received, it would be difficult to accurately detect the light reception timing, leading to an increase of a distance measurement error.

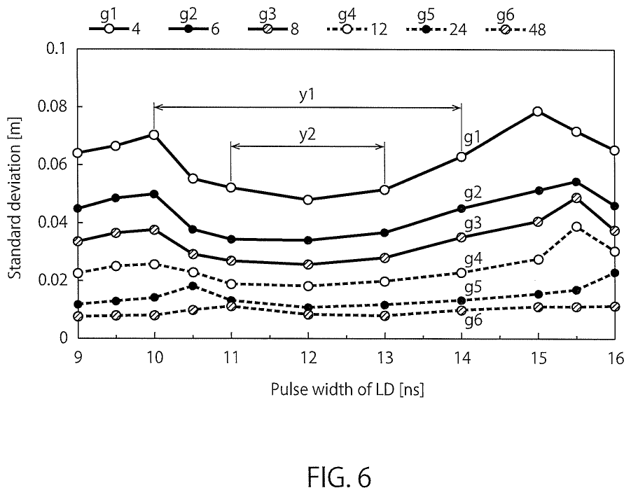

The inventors have found that adjusting the pulse width at which the light projecting unit 2 projects the laser beam will change the distance measurement error. FIG. 6 is a diagram illustrating a relationship between a pulse width of the laser beam projected by the light projecting unit 2 and a distance measurement error. In FIG. 6, the number of received photons is 1177, and the dead time of the APD 36 is 5 ns. The horizontal axis in FIG. 6 is the pulse width [ns], and the vertical axis is the distance measurement error [m]. FIG. 6 illustrates graphs g1 to g6 respectively illustrate cases where the number of APDs 36 included in SiPM 37 is 4, 6, 8, 12, 24, and 48.

As observed from the graphs g1 to g6 in FIG. 6, the more the number of APDs 36, the less the distance measurement error. Regardless of the number of APDs 36 in the SiPM 37, the distance measurement error is maximized when the pulse width of the laser beam projected by the light projecting unit 2 is an integral multiple of the dead time of the APD 36 (for example, the pulse widths in FIG. 6 are 10 ns and 15 ns). Accordingly, in order to reduce the distance measurement error, it is obviously desirable to shift the pulse width of the laser beam projected by the light projecting unit 2 from an integral multiple of the dead time of the APD 36.

Therefore, the light projecting unit 2 according to the present embodiment continuously projects a laser beam during a period of a pulse width that is not an integral multiple of the dead time of the APD 36. Since the dead time of the APD36 can be adjusted at a design stage of the APD36, the light projection control unit 12 can control so that the pulse width of the laser beam projected by the light projecting unit 2 is not an integral multiple of the dead time on the basis of the information regarding the dead time of the APD36.

More preferably, as illustrated by arrow line y1 in FIG. 6, the light projecting unit 2 emits a laser beam having a pulse width greater than n times the dead time (n is an integer of 1 or more) of the APD 36, and smaller than (n+1) times the dead time by 20% of the dead time or more.

Still more preferably, as illustrated by arrow line y2 in FIG. 6, the light projecting unit 2 emits a laser beam having a pulse width greater than n times the dead time of the APD 36 by 20% of the dead time or more, and smaller than (n+1) times the dead time by 40% of the dead time or more. Such a pulse width control can also be performed by the light projection control unit 12.

In this manner, adjusting the pulse width so that the pulse width of the laser beam projected by the light projecting unit 2 is not an integral multiple of the dead time of the APD 36 would be able to further increase the number of photons received by the light receiving sensor 34, resulting in the reduction of the distance measurement error in the measurement on the distance measurement unit 42.

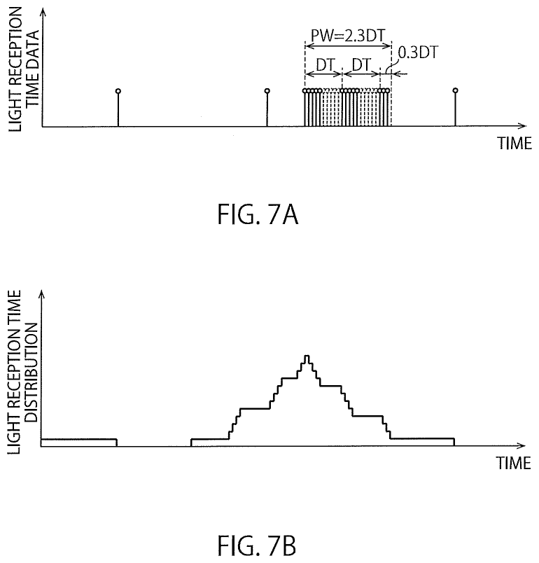

FIGS. 7A and 7B are diagrams illustrating light reception time data and light reception time distribution of the light receiving sensor 34 when the pulse width of the laser beam projected by the light projecting unit 2 is 2.3 times the dead time of the APD 36. In FIGS. 7A and 7B, the pulse width of the laser beam projected by the light projecting unit 2 is (2.3−2=0.3) times longer than the dead time of the APD 36, compared to the case of FIGS. 6A and 6B. With this configuration, while four photons can be received twice during the reflected light reception period in FIG. 6A, it is possible, in FIG. 7A, to receive photons one more time, and to reliably increase the number of photons received by the light receiving sensor 34. Therefore, the light reception time distribution illustrated in FIG. 7B spreads over a wider range than in FIG. 6B, and the light reception timing of the reflected light can be detected with higher accuracy.

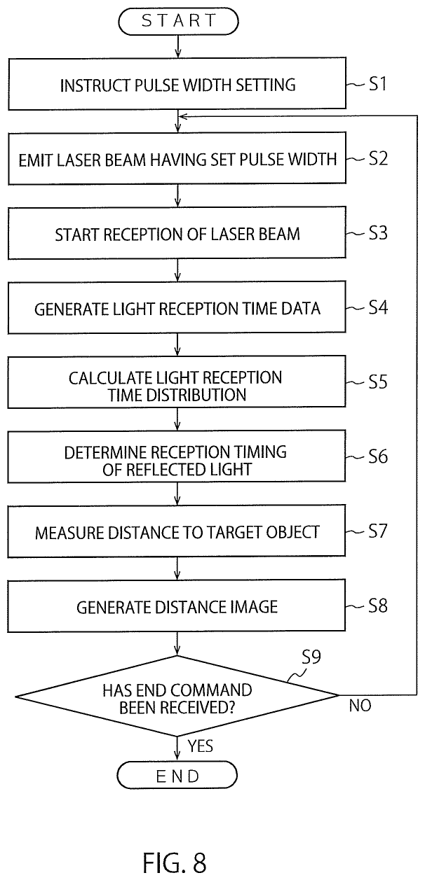

FIG. 8 is a flowchart illustrating processing operation of the electronic device 1 according to the present embodiment. At the start of the processing of FIG. 8, it is assumed that the pulse width of the laser beam projected by the light projecting unit 2 has been set to a value that is not an integral multiple of the dead time of the APD 36 according to graphs g1 to g6 of FIG. 6.

The light projection control unit 12 transmits a control signal to the oscillator 11 so that the light source 13 emits a laser beam having a set pulse width (step S1). The first drive unit 14 generates a drive signal for driving the light source 13 in accordance with the oscillation signal generated by the oscillator 11. This causes the light source 13 to emit a laser beam having a set pulse width (step S2).

When the laser beam is emitted from the light source 13, the light receiving sensor 34 starts to receive light, and the received light signal is converted into an electrical signal by the A/D converter 35 (step S3). The control unit 43 generates light reception time data regarding the time of reception of the laser beam on the basis of the electrical signal converted by the A/D converter 35 (step S4). The light reception time data is as illustrated in FIG. 7A.

Next, the control unit 43 calculates a light reception time distribution on the basis of the light reception time data (step S5). As illustrated in FIG. 7B, the light reception time distribution is distribution of the number of photons received within a period having the same length as the pulse width of the laser beam projected by the light projecting unit 2.

Next, the control unit 43 determines the light reception timing of the reflected light on the basis of the light reception time distribution (step S6). In step S6, the control unit 43 determines the light reception timing corresponding to the peak value of the light reception time distribution of FIG. 7B, for example. Alternatively, the control unit 43 may determine the light reception timing using the average value of the light reception time distribution in FIG. 7B.

Next, the distance measurement unit 42 measures the distance to the target object on the basis of a time difference between the light projection timing at which the light projecting unit 2 projects the laser beam, that is, the timing at which the light source 13 in the light projecting unit 2 emits the laser beam, and the light reception timing determined in step S6, using the above-described Formula (1) (step S7). On the basis of the measured distance, the image processing unit 6 generates a distance image obtained by imaging the distance to each of target objects existing around the electronic device 1 (step S8).

Next, it is determined whether a processing end command has been received (step S9). In a case where the command has not been received yet, the processing from step S1 will be repeated. In a case where the end command has been received, the processing of FIG. 8 will be finished.

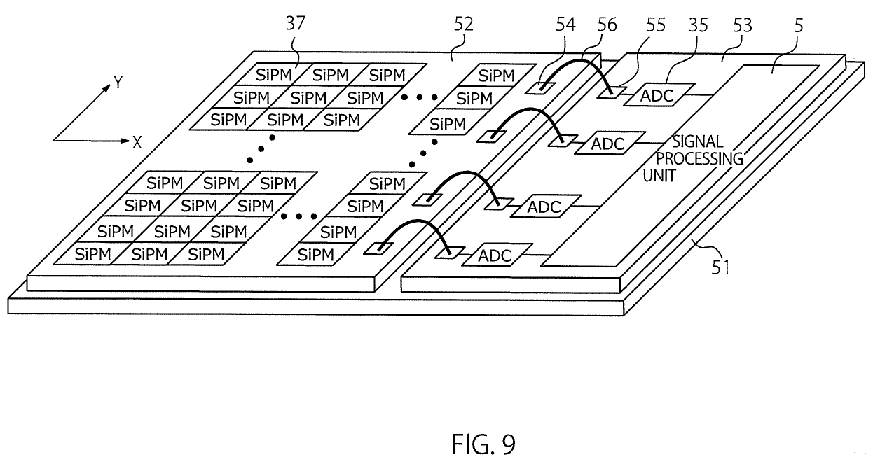

At least a part of the electronic device 1 according to the present embodiment can be mounted on a semiconductor substrate such as a silicon on insulator (SOI) substrate. FIG. 9 is a schematic perspective view illustrating an example in which the light receiving unit 4 and the signal processing unit 5 are mounted on a semiconductor substrate. There are a first die 52 and a second die 53 provided on a semiconductor substrate 51 of FIG. 9. On the first die 52, the light receiving sensor 34 in the light receiving unit 4 of FIG. 1 is disposed. As illustrated in FIG. 8, the light receiving sensor 34 includes a plurality of SiPMs 37 arranged in the X direction and the Y direction. On the second die 53, the A/D converter (ADC) 35 and the signal processing unit 5 in the light receiving unit 4 of FIG. 1 are disposed. A pad 54 on the first die 52 and a pad 55 on the second die 53 are connected by a bonding wire 56.

In the layout image of FIG. 9, a plurality of SiPMs 37 is arranged on the first die 52. Alternatively, an active quench circuit and a passive quench circuit for reducing the dead time of the APD 36 may be arranged corresponding to each of the SiPMs 37.

In this manner, in the present embodiment, the pulse width of the laser beam projected by the light projecting unit 2 is set to a value that is not an integral multiple of the dead time of the APD 36, that is, the pulse width different from any of n times the dead time (n is an integer of 1 or more). This makes it possible to increase the number of photons received by the light receiving unit 4 compared with the case where the pulse width is an integral multiple of the dead time. This enables detection of the light reception timing of the reflected light with higher accuracy, leading to the reduction of the distance measurement error. In the setting of the pulse width of the laser beam projected by the light projecting unit 2, as illustrated in FIG. 5, an optimum pulse width is set on the basis of the correspondence between the pulse width of the laser beam projected by the light projecting unit 2 and the distance measurement error, making it possible to minimize the distance measurement error. According to the present embodiment, in a case where the dead time exists in the APD 36, it is possible to suppress the influence of the dead time without changing the APD 36 itself.

The control of the pulse width of the laser beam projected by the light projecting unit 2 as described above can be implemented together with a remedy for reducing the dead time by providing an active quench circuit or a passive quench circuit in the APD 36.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. An electronic apparatus comprising:
a light detector configured to detect light by converting a reception photon into a signal and incapable of converting an additional photon into the signal during a recovery period after a reception of photons;
a light projector configured to project light having a pulse width different from any of n times the recovery period (n is an integer of 1 or more); and
a processor configured to measure a distance to a target object by using a time difference between a timing at which light is projected by the light projector and a timing at which light comprising a reflected wave is detected by the light detector, wherein the reflected wave is obtained by reflection of the light projected by the light projector onto the target object.

2. The electronic apparatus according to claim 1,
wherein the light projector is configured to project the light having the pulse width that is greater than n times the recovery period, and smaller than (n+1) times the recovery period by 20% of the recovery period or more.

3. The electronic apparatus according to claim 2,
wherein the light projector has a pulse width greater than n times the recovery period by 20% of the recovery period or more, and smaller than (n+1) times the recovery period by 40% of the recovery period or more.

4. The electronic apparatus according to claim 2,
wherein the light detector determines the light reception timing of the reflected wave on the basis of light reception signals received before and after the recovery period.

5. The electronic apparatus according to claim 1,
wherein the light detector comprises an avalanche photodiode, and
the light detector receives light in a Geiger mode in which a reverse bias voltage higher than a breakdown voltage is applied between an anode and a cathode of the avalanche photodiode.

6. The electronic apparatus according to claim 5,
wherein the light detector comprises a plurality of the avalanche photodiodes arranged in one direction or two directions,
a plurality of first avalanche photodiodes out of the plurality of avalanche photodiodes receives light incident from a first direction, and
a plurality of second avalanche photodiodes out of the plurality of avalanche photodiodes receives light incident from a second direction different from the first direction.

7. The electronic apparatus according to claim 6,
wherein the light detector comprises a light receiving sensor in which a plurality of diode groups each having the plurality of avalanche photodiodes, as a unit, is arranged in one direction or two directions, and
each of the diode groups receives light incident from a corresponding direction.

8. A light detector apparatus configured to receive reflected light having a pulse width and obtained by reflection of project light onto a target object,
the apparatus comprising
a light detector configured to detect light by converting a reception photon into a signal and incapable of converting an additional photon into the signal during a recovery period after a reception of photons, and
a terminal configured to output the signal,
wherein a length of the recovery period is set to satisfy a relationship that the pulse width is different from any of n times the recovery period (n is an integer of 1 or more).

9. The light receiving apparatus according to claim 8 further comprising a processor that measures a distance to a target object by using a time difference between a timing at which light is projected by the light projector and a timing at which light comprising a reflected wave is detected by the light detector, wherein the reflected wave is obtained by reflection of the light projected by the light projector onto the target object, the light projector projecting light having a pulse width different from any of n times the recovery period (n is an integer of 1 or more).

10. The light receiving apparatus according to claim 8,
wherein the light detector determines the light reception timing of the reflected wave on the basis of light reception signals received before and after the recovery period.

11. The light receiving apparatus according to claim 8,
wherein the light detector comprises an avalanche photodiode, and
the light detector receives light in a Geiger mode in which a reverse bias voltage higher than a breakdown voltage is applied between an anode and a cathode of the avalanche photodiode.

12. The light receiving apparatus according to claim 11,
wherein the light detector comprises a plurality of the avalanche photodiodes arranged in one direction or two directions,
a plurality of first avalanche photodiodes out of the plurality of avalanche photodiodes receives light incident from a first direction, and
a plurality of second avalanche photodiodes out of the plurality of avalanche photodiodes receives light incident from a second direction different from the first direction.

13. The light receiving apparatus according to claim 12,
wherein the light detector comprises a light receiving sensor in which a plurality of diode groups each having the plurality of avalanche photodiodes, as a unit, is arranged in one direction or two directions, and
each of the diode groups receives light incident from a corresponding direction.

14. A light projector apparatus configured to project light having a pulse width, the light to be reflected by a target object and to be detected by a light detector having a recovery period incapable of detecting an additional photon after a reception of photons,
the light projecting apparatus comprising
a light projector configured to project light having a pulse width different from any of n times the recovery period (n is an integer of 1 or more).

15. A distance measurement method comprising:
continuously projecting light from a light projector during a pulse width that is not an integral multiple of a recovery period in which a light detector is incapable of newly receiving light after receiving a predetermined number of photons; and
measuring a distance to a target object by using a time difference between a timing at which light is projected by the light projector and a timing at which light comprising a reflected wave is detected by the light detector, wherein the reflected wave is obtained by reflection of the light projected by the light projector onto the target object.

16. The distance measurement method according to claim 15,
wherein the light projector is configured to project the light having the pulse width that is greater than n times the recovery period, and smaller than (n+1) times the recovery period by 20% of the recovery period or more.

17. The distance measurement method according to claim 16,
wherein the light projector has a pulse width greater than n times the recovery period by 20% of the recovery period or more, and smaller than (n+1) times the recovery period by 40% of the recovery period or more.

18. The distance measurement method according to claim 16,
wherein the light detector determines the light reception timing of the reflected wave on the basis of light reception signals received before and after the recovery period.

19. The distance measurement method according to claim 15,
wherein the light detector receives light in a Geiger mode in which a reverse bias voltage higher than a breakdown voltage is applied between an anode and a cathode of an avalanche photodiode.

20. The distance measurement method according to claim 19,
wherein the light detector is provided with a plurality of the avalanche photodiodes arranged in one direction or two directions,
a plurality of first avalanche photodiodes out of the plurality of avalanche photodiodes receives light incident from a first direction, and
a plurality of second avalanche photodiodes out of the plurality of avalanche photodiodes receives light incident from a second direction different from the first direction.
